(19) United States
(12) Patent Application Publication
(10) Pub. No.: US 2001/0053070 A1
(43) Pub. Date: Dec. 20, 2001

(54) Electronic unit equipped with electromagnetic shielding plate

(75) Inventors: Nobuyuki Kitamura, Shioya-gun (JP); Satoshi Kikuchi, Shioya-gun (JP)

Correspondence Address: ARMSTRONG,WESTERMAN, HATTORI,, MCLELAND & NAUGHTON, LLP, 1725 K STREET, NW, SUITE 1000, WASHINGTON, DC, 20006, US

(73) Assignee: KEIHIN CORPORATION, Tokyo (JP)

(21) Appl. No.: 09/880,893

(22) Filed: Jun. 15, 2001

(30) Foreign Application Priority Data
Jun. 19, 2000 (JP) 2000-182620

(51) Int. Cl. H05K 9/00

(52) U.S. Cl. 361/818; 361/816

(57) ABSTRACT

An electronic unit having an electronic circuit board, electronic components mounted on the electronic circuit board, and an electromagnetic shielding plate for blocking electromagnetic radiation emitted by one or more electronic components mounted on the electronic circuit board. The electromagnetic shielding plate having a sidewall that is formed with slits, is formed at a lower edge thereof with leg portions for connecting the electronic circuit board and is formed with gap portions for passing patterned wiring of the electronic circuit board by cutting away portions of the lower edge other than the leg portions. With this, it is possible to provide an electromagnetic shielding plate that does not interfere with the patterned wiring of the circuit board, does not reduce the mounting area of the circuit board and is excellent in heat dissipation property owing to excellent air-flow property in its inner space, thereby improving the reliability and packing density.

### BACKGROUND OF THE INVENTION

1. Field of the Invention

This invention relates to an electronic unit equipped with an electromagnetic shielding plate, specifically to an electronic unit that includes a circuit board carrying electronic components and is equipped with an electromagnetic shillding plate (electromagnetic raditation or wave shielding plate) for blocking electromagnetic radiation emitted by one or more of the electronic components.

2. Description of the Related Art

Central processing units (CPUs) and some other electronic components commonly mounted on circuit boards emit electromagnetic radiation or wave at specific frequencies. Depending on the frequency, this radiation may affect other electronic components on the circuit board. An electromagnetic shielding plate made of metal is therefore used to shield the other components from the radiation.

The conventional electromagnetic shielding plate encloses an electronic component that is a source of electromagnetic radiation, i.e., covers the entire upper and side surface of the component. Since interference therefore arises between the wiring patterned on the circuit board and the lower edge of the electromagnetic shielding plate sidewall, the wiring may be damaged or, in extreme cases, even broken.

As shown in FIG. 8, therefore, when an electromagnetic shield 100 is provided on a circuit board 102 patterned with wiring 106, damage or breakage of the wiring 106 is prevented by forming plated bypass through-holes 104 in the circuit board 102 inward and outward of the electromagnetic shield 100 so that the wiring 106 can bypass the bottom edge of the electromagnetic shield 100 via the through-holes 104 and the undersurface of the circuit board 102.

When the circuit board is to be used in an environment requiring vibration and/or moisture resistance, the circuit board and the electronic components mounted on it are preferably integrally encased in molded resin so as to protect the lead portions and soldered portions of the electronic components from solder cracking and lead portion breakage caused by vibration and also prevent short-circuiting owing to presence of moisture.

As the conventional electromagnetic shielding plate completely encloses the electronic component that is a source of radiation, however, resin cannot be charged or potted into the inner space of the shielding plate. The air trapped in the inner space of the shielding plate may therefore release moisture owing to change in temperature, pressure etc. When this happens, the lead portions of the electronic component are liable to be oxidized.

Japanese Laid-Open Patent Application Hei 9 (1997)-266382, for example, teaches coping with this problem by penetrating a through-hole in the circuit board to communicate with the inner space difficult to charge with resin so that resin can be charged or potted into the inner space via the through-hole from the underside of the circuit board.

When damage and breakage of the wiring is prevented by running the wiring along the bypass through-holes at the undersurface of the circuit board as mentioned above, the bypass through-holes must be formed in the circuit board. This is disadvantageous because it markedly constrains the electronic component mounting locations and the wiring pattern design inside the electromagnetic shielding plate and also reduces the area of the circuit board available for mounting components (the mounting area). The same disadvantages also arise when the penetrated through-hole for charging resin is formed through the circuit board into the space that is hard to charge with resin, as mentioned above.

Since the air trapped in the inner space of the electromagnetic shielding plate cannot readily flow, moreover, heat is apt to accumulate under the plate. In other words, the heat dissipation property is poor.

The electromagnetic shielding plate is ordinarily mounted on (connected to) the electronic circuit board by insertion mounting or surface mounting. When it is insertion-mounted, leg portions provided on the electromagnetic shielding plate (corresponding to the lead portion of an electronic component) are inserted into through-holes formed in the electronic circuit board. It can therefore be reliably mounted without any positional shift.

However, owing to the fact that the electromagnetic shielding plate directly abuts on the electronic circuit board at certain places and that the electromagnetic shielding plate is made of metal, the surface portions of the electronic circuit board contacted by the electromagnetic shielding plate are liable to be damaged when the circuit board experiences vibration or the like.

On the other hand, when the electromagnetic shielding plate is surface-mounted, the packing density of the electronic circuit board can be improved, no leg portions or through-holes are necessary, and reliable mounting with a simple structure is possible. In addition, the reliability of an electronic unit utilizing the electronic circuit board is enhanced because the reliability (strength) of leg portions is not an issue.

However, owing to the fact that surface mounting is achieved by placing a pad coated with cream solder at the surface of contact between the electromagnetic shielding plate and the electronic circuit board and conducting reflow, a solder bridge is liable to be formed between the electromagnetic shielding plate and the wiring pattern near the electromagnetic shielding plate at the time of reflow. Specifically, the electromagnetic shielding plate and the wiring pattern are apt to be electrically connected by solder to give rise to short-circuiting.

### SUMMARY OF THE INVENTION

An object of this invention is therefore to provide an electronic unit equipped with an electromagnetic shielding plate that does not interfere with the wiring pattern of the electronic circuit board, does not constrain the wiring pattern design, does not reduce the mounting area of the electronic circuit board and is excellent in heat dissipation property owing to excellent air-flow property in its inner space; to provide an electromagnetic shielding plate whose inner space can be charged or potted with resin; and thereby to provide an electronic unit equipped with an electromagnetic shielding plate that is improved in reliability and packing density.

Another object of the present invention is to provide an electronic unit equipped with an electromagnetic shielding plate which, when insertion-mounted or surface-mounted on an electronic circuit board, does not damage the surface of the electronic circuit board, i.e., surface portions thereof contacted by the electromagnetic shielding plate, and which prevents formation of a solder bridge between the electromagnetic shielding plate and the wiring pattern; and thereby to provide an electronic unit equipped with an electromagnetic shielding plate that is improved in reliability.

For realizing these objects, in a first aspect, this invention provides an electronic unit comprising an electronic circuit board, electronic components mounted on the electronic circuit board, and an electromagnetic shielding plate for blocking electromagnetic radiation emitted by one or more electronic components mounted on the electronic circuit board, wherein the electromagnetic shielding plate is formed at a lower edge thereof with leg portions for connecting the electronic circuit board and is formed with a gap portion for passing patterned wiring of the electronic circuit board by cutting away portions of the lower edge other than the leg portions.

Since the sidewall of the electromagnetic shielding plate is formed at the lower edge thereof with leg portions for connecting the electronic circuit board and is formed with gap portions for passing patterned wiring of the electronic circuit board by cutting away portions of the lower edge other than the leg portions, it is possible to provide an electromagnetic shielding plate that does not interfere with the patterned wiring of the circuit board, does not reduce the mounting area of the circuit board and is excellent in heat dissipation property owing to excellent air-flow property in its inner space. As a result, the reliability and packing density of an electronic unit equipped with the electromagnetic shielding plate can be improved.

Moreover, damage to the surface of the electronic circuit board, i.e., surface portions thereof contacted by the electromagnetic shielding plate, and formation of a solder bridge between the electromagnetic shielding plate and the wiring pattern can be prevented during insertion mounting or surface mounting of the electromagnetic shielding plate on the electronic circuit board.

In a second aspect of the invention, connecting portions for connection with the leg portions are constituted as through-holes for insertion of the leg portions.

Since the connecting portions are constituted as through-holes for insertion of the leg portions, i.e., more generally speaking so that the electromagnetic shielding plate can be insertion-mounted on the electronic circuit board, the electromagnetic shielding plate can be reliably mounted on the electronic circuit board without positional shifting. The reliability of the electronic unit equipped with the electromagnetic shielding plate is therefore further improved.

In a third aspect of the invention, connecting portions for connection with the leg portions are constituted as pads on which the leg portions are mounted.

Since the connecting portions are constituted as pads on which the leg portions are mounted, i.e., more generally speaking so that the electromagnetic shielding plate can be surface-mounted on the electronic circuit board, the packing density of the electronic circuit board can be improved and the electromagnetic shielding plate can be reliably mounted on the electronic circuit board with a simple structure. The reliability of the electronic unit equipped with the electromagnetic shielding plate is therefore further improved.

In a fourth aspect of the invention, the electromagnetic shielding plate has the sidewall that is formed with a slit.

In a fifth aspect of the invention, at least one member of the group composed of the slit and the gap portion is constituted as inlets for enabling resin to flow into an inner portion of the electromagnetic shielding plate when the electronic circuit board is integrally encased in molded resin.

Since the slit and/or the gap portion are constituted as inlets for enabling resin to flow into an inner portion of the electromagnetic shielding plate when the electronic circuit board is integrally encased in molded resin, i.e., since charging of the inner portion of the electromagnetic shielding plate with resin is enabled, the resistance of the lead portions against vibration and oxidation is improved. The reliability of the electronic unit equipped with the electromagnetic shielding plate is therefore further improved.

In a sixth aspect of the invention, areas of the electronic circuit board surrounding the connecting portions for connection with the leg portions being subjected to silk-screen printing.

With this, the surface of the circuit board can surely be protected by the silk-screen printed portions. The silk-screen printed portions also function as markings indicating the mounting location of the shielding plate.

### BRIEF DESCRIPTION OF THE DRAWINGS

FIG. 1 is a perspective view showing an electronic unit equipped with an electromagnetic shielding plate according to an embodiment of the present invention;

FIG. 2 is a perspective view of the electromagnetic shielding plate of FIG. 1;

FIG. 3A and FIG. 3B are side views of the electromagnetic shielding plate shown in FIG. 2;

FIG. 4 is a perspective view for explaining mounting (insertion mounting) of the electromagnetic shielding plate of FIG. 2 on a circuit board;

FIG. 5 is a perspective view for explaining how the electronic unit equipped with the electromagnetic shielding plate shown in FIG. 1 is encased in molded resin;

FIG. 6 is a perspective view of an electromagnetic shielding plate shown separately of an electronic unit according to a second embodiment of the present invention;

FIG. 7 is a perspective for explaining mounting (surface mounting) of the electromagnetic shielding plate of FIG. 6 on a circuit board; and

FIG. 8 is a sectional view showing patterned wiring connection when a conventional electromagnetic shielding plate is mounted on a circuit board.

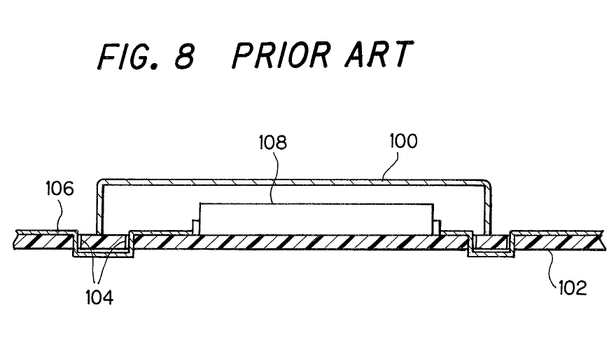

### DETAILED DESCRIPTION OF THE PREFERRED EMBODIMENTS

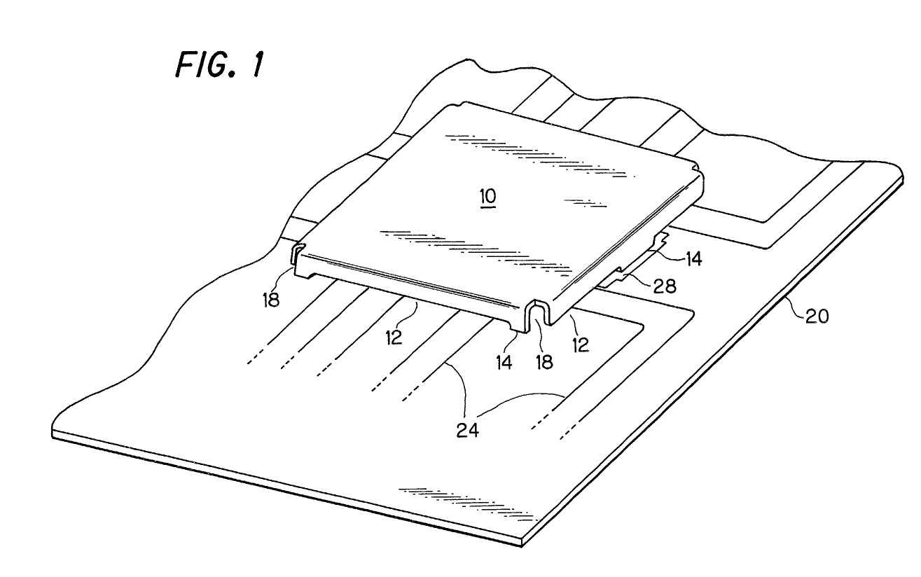

An electronic unit equipped with an electromagnetic shielding plate according to a first embodiment of the present invention will now be explained with reference to FIGS. 1 to 5.

FIG. 1 is a perspective view showing an electronic unit equipped with an electromagnetic shielding plate according to a first embodiment of the present invention, specifically an electronic unit equipped with a circuit board having electronic components mounted thereon and an electromagnetic shielding plate. The electromagnetic shielding plate (more precisely, electromagnetic radation or wave shilding plate), designated by reference numeral 10 (hereinafter referred to simply as “shielding plate”), is formed or fabricated by pressing metal sheet material into a box-like shape that is approximately rectangular as viewed from the top and slightly larger than an electronic component explained later.

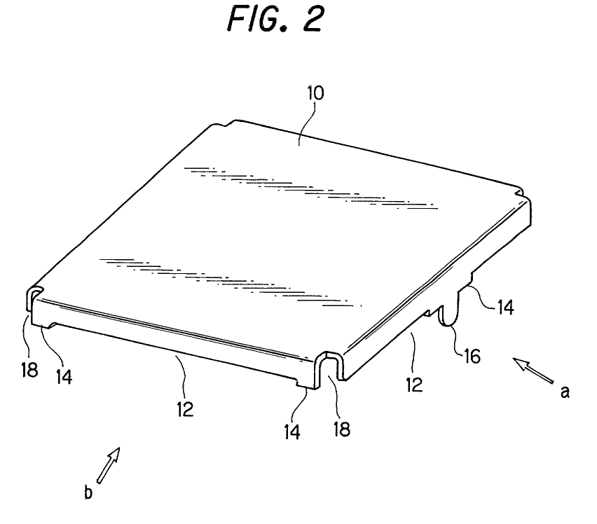

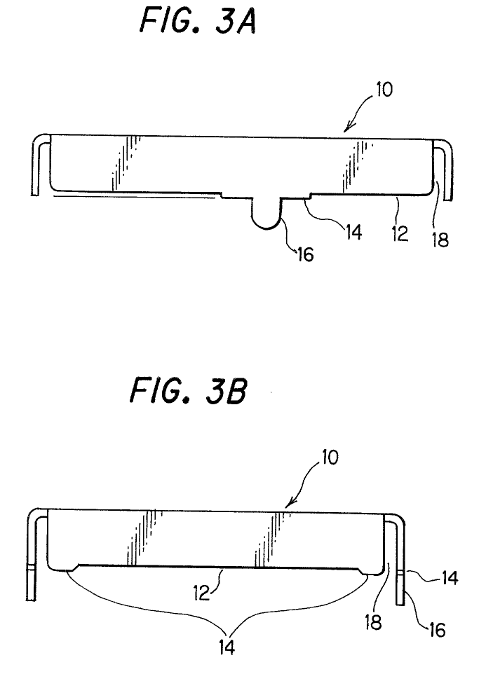

Before going into a detailed explanation of FIG. 1, the shielding plate 10 will first be explained with reference to FIGS. 2, 3A and 3B, in which it is shown separately of the electronic unit. The attachment of the electromagnetic shielding plate to the circuit board will also be explained first.

FIG. 2 is a perspective view of the electromagnetic shielding plate 10 shown separately of the electronic unit of the first embodiment.

The shielding plate 10 has a sidewall whose lower edge is formed with gap portions 12 formed by cutting away portions of the sidewall as appropriate for enabling passage of patterned wiring (described later). The lower end of the sidewall is also formed at appropriate locations with leg portions 14 that extend vertically downward and are used to support the shielding plate 10 on the circuit board (explained later). The lower end of each leg 14 is formed with a projecting portion 16 that also extends vertically downward and is intended for insertion into a through-hole (explained later) formed in the circuit board.

Each corner of the shielding plate 10 is formed with a slit 18 of prescribed width that extends from the upper edge to the lower edge of the sidewall. FIG. 3A is a side view of the shielding plate 10 seen in the direction of the arrow a in FIG. 2 and FIG. 3B is a side view thereof seen in the direction of the arrow b in FIG. 2.

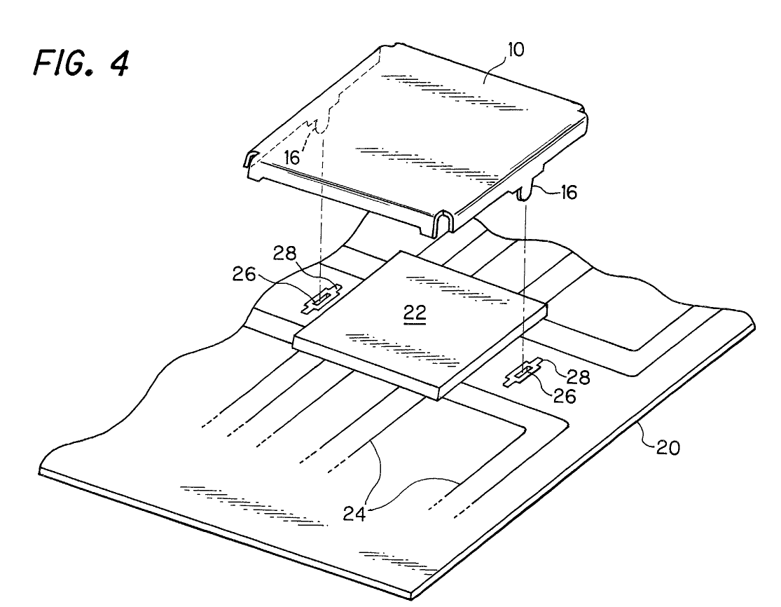

The circuit board and the attachment of the shielding plate 10 thereto will now be explained with reference to FIG. 4.

As shown in FIG. 4, a CPU or other electronic components (generally assigned with reference numeral 22) is mounted on an electronic circuit board 20. The electronic components 22 are connected to other electronic components etc. (not shown) by a plurality of patterned wires 24. The circuit board 20 is formed at appropriate locations with through-holes 26 for insertion of the projecting portions 16.

The through-holes 26 are given approximately the same shape as the projecting portions 16 so that the shielding plate 10 can be insertion-mounted on the circuit board 20 by insertion of the projecting portions 16 into the through-hole 26 in the illustrated manner. The areas surrounding the through-holes 26 are formed (printed) with silk-screen printed portions 28 matched to the shape of the leg portions 14.

As can be seen from FIG. 1, the shielding plate 10 is supported by the leg portions 14. Owing to the presence of the gap portions 12, moreover, gaps matched to the layout of the patterned wires 24 are formed between the shielding plate 10 and the circuit board 20. Since the patterned wires 24 pass through these gaps, no interference arises between the patterned wires 24 and the shielding plate 10. Thus no bypass through-holes for forming patterned wire bypasses need be formed and the wiring pattern design is not constrained. Therefore, reduction of mounting area can be avoided and packing density increased.

Further, the surface of the circuit board 20 is safe from damage because the portions of its surface contacted by the shielding plate 10, specifically by the leg portions 14 thereof, are protected by the silk-screen printed portions 28. The silk-screen printed portions 28 also function as markings indicating the mounting location of the shielding plate 10.

In addition, air can flow into and out of inner space of the shielding plate 10 through the slits 18. Heat is therefore not likely to accumulate in the electronic components 22 mounted inside the shielding plate 10. In other words, the heat dissipation property is improved.

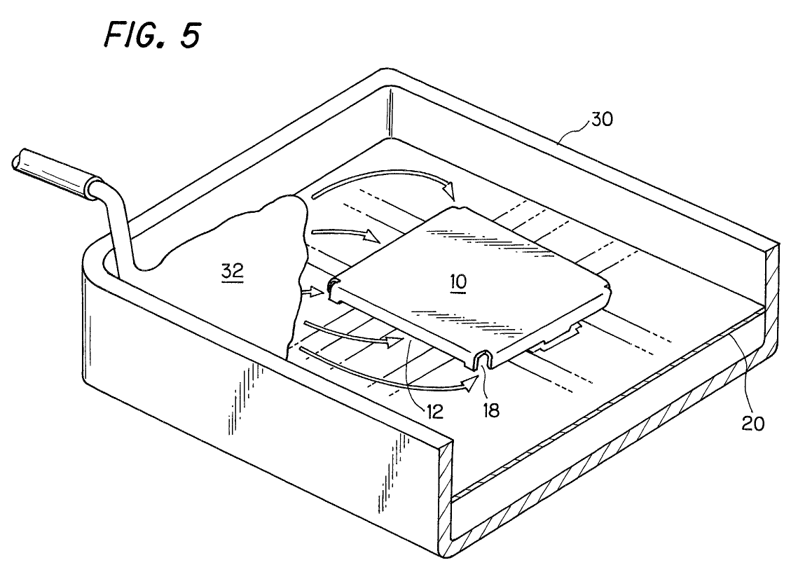

The circuit board 20 having the shielding plate 10 and the electronic components 22 mounted thereon is then encased in molded resin. This will be explained with reference to FIG. 5.

As illustrated in FIG. 5, the circuit board 20 with the shielding plate 10 and the electronic components 22 (not shown) mounted thereon is placed in a case 30 and resin 32 is poured into the case 30. The resin 32 passes through the slits 18 and the gap portions 12 into the interior of the shielding plate 10. As mentioned earlier, the slits 18 extend from the upper edge to the lower edge of the shielding plate sidewall. The resin 32 can therefore be charged or potted up to the top of the inner space without leaving any voids.

The electronic components 22 mounted in the inner space of the shielding plate 10 and the circuit board 20 can therefore integrally encased in molded resin without leaving any voids. The resistance of the lead portions and the soldered portions (neither shown) against vibration and oxidation is therefore effectively improved.

As explained in the foregoing, in the electronic unit equipped with an electromagnetic shielding plate according to this embodiment of the present invention, the electronic components 22 and the shielding plate 10 do not interfere with each other. Moreover, no constraint is placed on the wiring pattern design. Therefore, reduction of mounting area can be avoided and packing density increased.

Further, since the circuit board is covered by resin, the surface of the circuit board 20 is safe from damage. In addition, the mounting of the shielding plate 10 is facilitated because the mounting location of the shielding plate 10 is marked.

Still further, heat generated by the electronic components 22 mounted inside the shielding plate 10 is not likely to accumulate therein. In other words, the heat dissipation property is improved.

Moreover, during the encasement in molded resin, the resin 32 can be charged or potted between the electronic components 22 mounted in the inner space of the shielding plate 10 and the circuit board 20 without leaving any voids. The electronic components 22 and the circuit board 20 can therefore be integrally encased in molded resin to effectively improve the vibration and oxidation resistance of the lead portions of the electronic components 22.

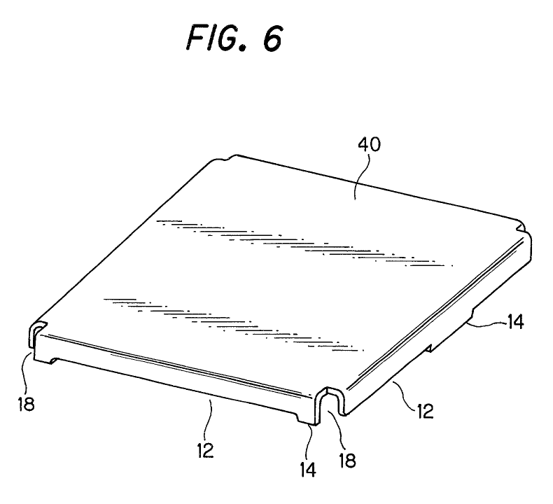

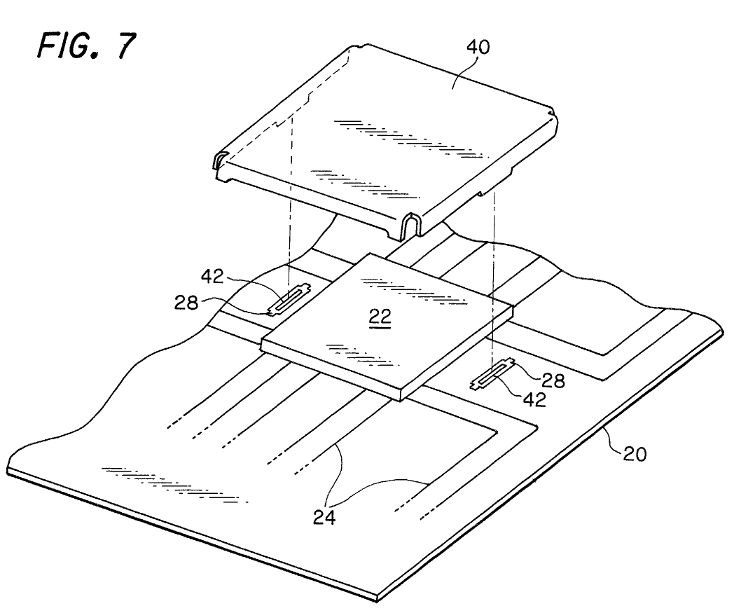

An electronic unit equipped with an electromagnetic shielding plate according to a second embodiment of the present invention will now be explained with reference to FIGS. 6 and 7.

In FIG. 6, the shielding plate of the electronic unit according to the second embodiment is designated by reference numeral 40. It differs from the shielding plate 10 in the point of not being provided with the projecting portions 16. As shown in FIG. 7, moreover, pads 42 coated with cream solder are disposed at the surface of contact between the leg portions 14 and the circuit board 20 instead of the through-holes 26.

The leg portions 14 are placed on the pads 42 in the illustrated manner and the surface mounting of the shielding plate 40 on the circuit board 20 is then completed by conducting reflow. This surface mounting provides the aforesaid effects and advantages by means of a still simpler structural arrangement and also improves the packing density of the circuit board 20.

It further ensures that no solder bridge is formed between the shielding plate 40 and the patterned wiring 24 by pooling of molten cream solder (not shown) at the silk-screen printed portion 28 during the reflow process. Another advantage is that the reliability of the electronic unit is enhanced because the reliability (strength) of leg portions is not an issue.

As the remaining structural elements of the shielding plate 40 are the same as those of the shielding plate 10, they are assigned like reference numerals and will not be explained again.

Thus in each of the first and second embodiments of the present invention, the electronic unit comprises an electronic circuit board 20, electronic components 22 mounted on the electronic circuit board 20, and an electromagnetic shielding plate 10 (40) for blocking electromagnetic radiation emitted by one or more electronic components mounted on the electronic circuit board 20, the electromagnetic shielding plate 10 (40) having a sidewall is formed at a lower edge thereof with leg portions (14) for connecting the electronic circuit board and is formed with a gap portion 12 for passing patterned wiring of the electronic circuit board by cutting away portions of the lower edge other than the leg portions 14, areas of the electronic circuit board 20 surrounding connecting portions (through-holes 26, pads 42) for connection with the leg portions 14 being subjected to silk-screen printing (silk-screen printed portions 28). Although the gap portion (12) is formed at every sidewall of the shielding plate 10 in the embodiments, it may thus be formed at only one sidewall or two sidewalls facing to each other.

In one configuration, connecting portions 14 for connection with the leg portions are constituted as through-holes 26 for insertion of the leg portions.

In another configuration, connecting portions 14 for connections with the leg portions are constituted as pads 42 on which the leg portions are mounted.

In still another configuration, the electromagnetic shielding plate 10 (40) has the sidewall that is formed with a slit (18). Although the slit is formed at every corner of the shielding plate 10 in the embodiment, it may thus be provided at one or some of the corner of the shielding plate.

In yet still another configuration, at least one member of the group composed of the slit 18 and the gap portion 12 is constituted as inlets for enabling resin 32 to flow into an inner portion of the electromagnetic shielding plate 10 (40) when the electronic circuit board 20 is integrally encased in molded resin 32.

In yet still another configuration, areas of the electronic circuit board 20 surrounding the connecting portions (through-holes 26, pads 42) for connection with the leg portions 14 being subjected to silk-screen printing (silk-screen printed portions 28).

In the foregoing embodiments of the present invention, the shielding plate 10 (40) has an approximately rectangular shape. The invention is, however, not limited to this shape and the shielding plate 10 (40) can have any of various other shapes matched to the shape of the electronic component(s) mounted in its inner space.

In addition, patterned wires 24 can be led into the inner space of the shielding plate 10 (40) by passing them through the slits 18.

The entire disclosure of Japanese Patent Application No. 2000-182620 filed on Jun. 19, 2000, including specification, claims, drawings and summary, is incorporated herein in reference in its entirety.

While the invention has thus been shown and described with reference to specific embodiments, it should be noted that the invention is in no way limited to the details of the described arrangements but changes and modifications may be made without departing from the scope of the appended claims.

What is claimed is:

1. An electronic unit comprising:
an electronic circuit board,
electronic components mounted on the electronic circuit board, and
an electromagnetic shielding plate for blocking electromagnetic radiation emitted by one or more electronic components mounted on the electronic circuit board,
wherein the electromagnetic shielding plate is formed at a lower edge thereof with leg portions for connecting the electronic circuit board and is formed with a gap portions for passing patterned wiring of the electronic circuit board by cutting away a portion of the lower edge other than the leg portions.

2. An electronic unit according to claim 1, wherein connecting portions for connection with the leg portions are constituted as through-holes for insertion of the leg portions.

3. An electronic unit according to claim 1, wherein connecting portions connection with the leg portions are constituted as pads on which the leg portions are mounted.

4. An electronic unit according to claim 1, wherein the gap portion is constituted as inlets for enabling resin to flow into an inner portion of the electromagnetic shielding plate when the electronic circuit board is integrally encased in molded resin.

5. An electronic unit according to claim 1, wherein the electromagnetic shielding plate has the sidewall that is formed with a slit.

6. An electronic unit according to claim 5, wherein the slit is constituted as inlets for enabling resin to flow into an inner portion of the electromagnetic shielding plate when the electronic circuit board is integrally encased in molded resin.

7. An electronic unit according to claim 1, wherein areas of the electronic circuit board surrounding the connecting portions for connection with the leg portions is subjected to silk-screen printing.
